(19) United States
(12) Patent Application Publication
(10) Pub. No.: US 2025/0112442 A1
(43) Pub. Date: Apr. 3, 2025

(54) PHOTONIC DEVICE AND METHOD OF FABRICATING SAME

(71) Applicant: Taiwan Semiconductor Manufacturing Company LTD, Hsinchu (TW)

(72) Inventor: Shih-Yu Liao, Hsinchu (TW)

(21) Appl. No.: 18/375,330

(22) Filed: Sep. 29, 2023

(51) Int. Cl. H01S 5/10; H01S 5/026; H01S 5/22

(52) U.S. Cl. CPC H01S 5/1028; H01S 5/026; H01S 5/2214

(57) ABSTRACT

A photonic device, structure, and fabrication method that includes a substrate having a topside oxide layer formed thereon. The structure also includes a silicon layer that is formed on the topside oxide layer, and one or more waveguide components that are formed in the silicon layer. In addition, the structure includes a reflection device trench structure that is formed in the silicon layer, and which includes a first oblique plane, a bottom plane, and a second oblique plane. The photonic structure also includes a reflection device that is formed adjacent to the first oblique plane, and which has a reflection device angle relative to the bottom plane and configured to direct light into a waveguide component.

### BACKGROUND

As integrated circuits (ICs) become increasingly smaller and faster, electrical signals used in various types of ICs are also subject to increasing delays caused by capacitance, inductance, or resistance in the ICs. At a certain high speed and/or frequency, such delays become a design concern. To avoid potential signal delay issues, optical signals are used instead of electrical signals for data transmission in some situations.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a photonic device in accordance with some embodiments.

FIGS. 2A-2V are cross-sectional views of stages of fabricating a portion of the photonic device of FIG. 1 in accordance with some embodiments.

FIGS. 3A-3D are cross-sectional views of stages of fabricating a portion of the photonic device of FIGS. 1A-2V in accordance with some embodiments.

FIGS. 4A-4I are cross-sectional views of stages of fabricating a reflection device and a reflection device trench structure of the photonic device of FIG. 1 in accordance with some embodiments.

FIGS. 5A-5C are cross-sectional views of varying embodiments of the reflection device and the reflection device trench structure.

FIG. 6 is a flowchart of a method of fabricating a photonic device structure in accordance with some embodiments.

FIG. 7 is a flowchart of a method of fabricating a photonic device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “about” can be used to include any numerical value that can vary without changing the basic function of that value. When used with a range, “about” also discloses the range defined by the absolute values of the two endpoints, e.g., “about 2 to about 4” also discloses the range “from 2 to 4.” The term “about” may refer to plus or minus 10% of the indicated number.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example, all layers of the structure can be considered to be “on” the substrate, even though they do not all directly contact the substrate. The term “directly” may be used to indicate two layers directly contact each other without any layers in between them. In addition, when referring to performing process steps to the substrate, this should be construed as performing such steps to whatever layers may be present on the substrate as well, depending on the context.

Rib waveguides include a contact extending through a contact etch stop layer to contact a dopant region positioned underneath. Oxide hard masks or layers deposited on the contact etch stop layer may collapse during patterning of the contact etch stop layer and/or patterning of the contact itself. In accordance with some embodiments recited herein, a rib trench is used to prevent mask collapse during patterning of the etch stop layer. A light source, such as a laser or optical fiber, used in a photonic device, requires subsequent processing of the device for cutting, insertion, facet formation, and in the case of the laser, separate fabrication processes. In accordance with some embodiments, a photonic device is described wherein an external light source may be used without post device modification. That is, in some embodiments described herein, there is provided a photonic device having an integrated mirror component, formed within the photonic device, that directs external light sources to waveguides formed therein.

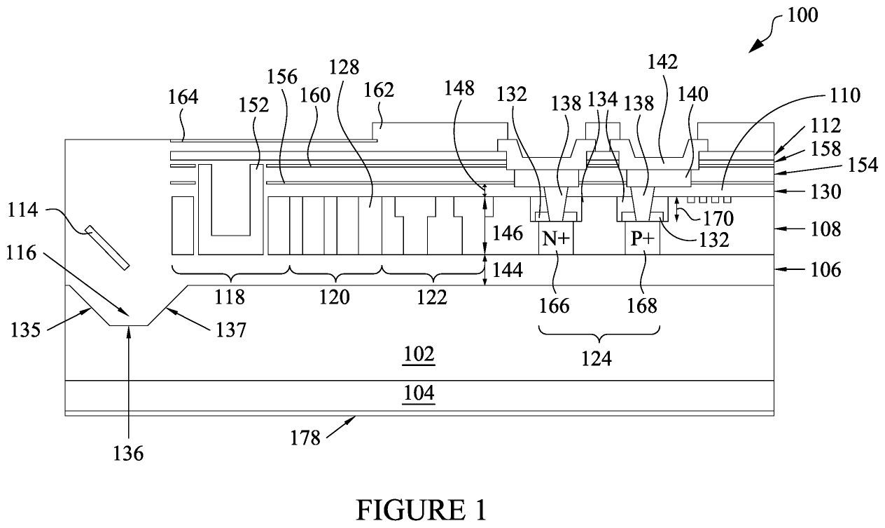

Turning now to FIG. 1, there is shown a photonic device 100 in accordance with one embodiment. As shown in FIG. 1, the photonic device 100 includes a substrate 102 having backside oxide layer 104 and a first topside oxide layer 106. In accordance with some embodiments, the substrate 102 may comprise, for example and without limitation, silicon, for example and without limitation, in the form of crystalline Si or polycrystalline Si. In alternative embodiments, the substrate 102 can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In accordance with one embodiment, the substrate 102 may be implemented as an SOI substrate, i.e., a silicon-on-insulator substrate. In such embodiments, the substrate 102 may comprise, for example and without limitation silicon oxide, or other suitable insulative material.

According to some embodiments, the backside oxide layer 104 and the first topside oxide layer 106 may comprise, for example and without limitation, non-low-k dielectric materials such as silicon oxide, silicon carbide (SIC), silicon carbo-nitride (SiCN), silicon oxy-carbo-nitride (SiOCN), or the like. In such embodiments, the backside oxide layer 104 and the first topside oxide layer 106 may have a thickness 144 in the range of 0.5 um to 3 um and in some embodiments, may have a thickness of 2 um. However, other values and ranges are also within the scope of this disclosure. As shown in FIG. 1, the photonic device 100 further includes a first silicon layer 108, formed on the first topside oxide layer 106. In accordance with some embodiments, the first silicon layer 108 may comprise a silicon, for example and without limitation, in the form of crystalline Si or polycrystalline Si. In accordance with some embodiments, the first silicon layer 108 may be implemented with a thickness 146 in the range of 1 um to 5 um, and in some embodiments, may have a thickness of 3 um. However, other values and ranges are also within the scope of this disclosure. A distributed Bragg reflector (“DBR”) 110 is formed on a top portion of the first silicon layer 108, as depicted in FIG. 1. It will be appreciated that the construction and/or location of the DBR 110 may be dependent upon the particular application for which the photonic device 100 is used, the needed wavelengths traveling therethrough, and the like.

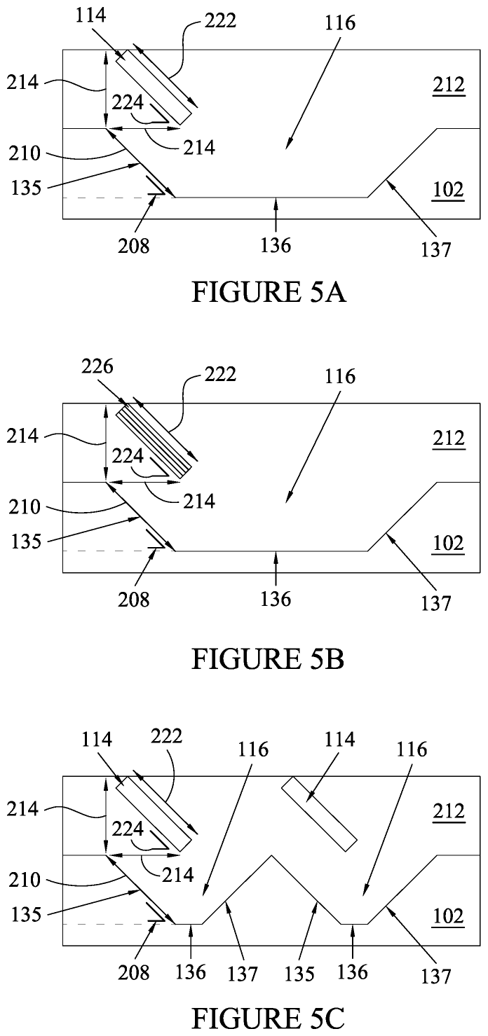

The photonic device 100 of FIG. 1 further includes a first etch stop layer 112, formed on portions of the substrate 102 and additional layers of the photonic device 100, as described herein. It will be appreciated that the first etch stop layer 112 may comprise any suitable barrier material configured to protect the layers and components below from damage during subsequent etching processes. The first etch stop layer 112 may be implemented as tantalum oxide (TaO), tantalum (Ta), titanium (Ti), silicon nitride (SiN), and the like. It will be appreciated that the first etch stop layer 112 corresponds to a layer of material that has drastically different etching characteristics than the material to be etched, so as to stop or halt the etching processing of the layer deposited on the etch stop layer. In accordance with one embodiment, a reflection device 114, e.g., a metal film, quarter-wave stack (high reflection coating/Bragg mirror, is formed from a material having suitable reflection characteristics within portions of the first top oxide layer 106 on one side of the photonic device 100, as shown in FIG. 1. In some embodiments, the reflection device 114 is positioned adjacent to a reflection device trench structure 116, extending downward into the substrate 102, as illustrated in FIG. 1. According to such embodiments, the reflection device 114 may comprise a metal alloy material, such as, for example and without limitation, Al, AlCu, AlSiCu, AlSi, AlCr, or the like. In other embodiments, the reflection device 114 may utilize a reflective coating or high reflection coating on a surface thereof, including, for example and without limitation, SiO2/TiOx, AlAs/GaAs, AlN/GaN, or the like. Example illustrations of the reflection device 114 are discussed in greater detail below with respect to FIGS. 5A-5C.

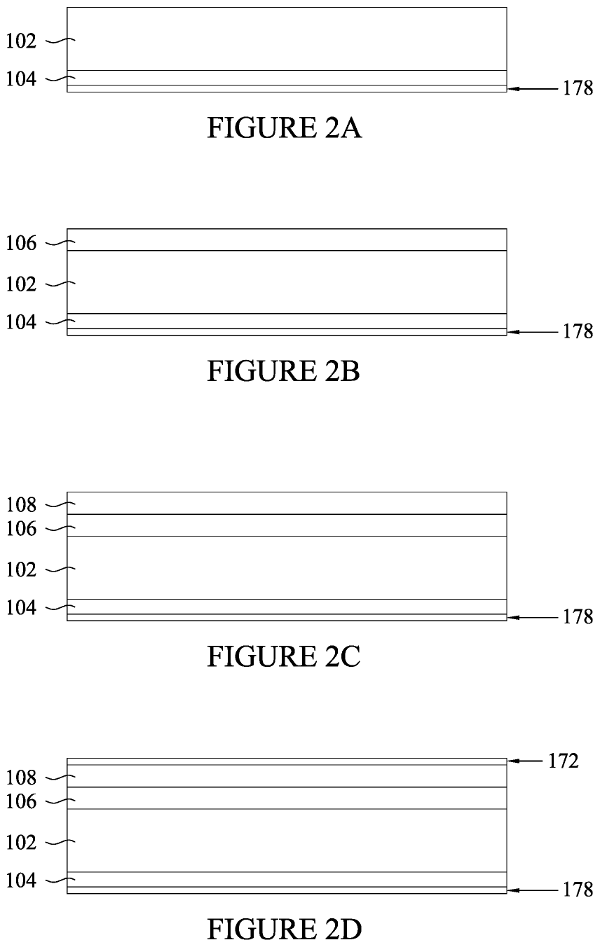

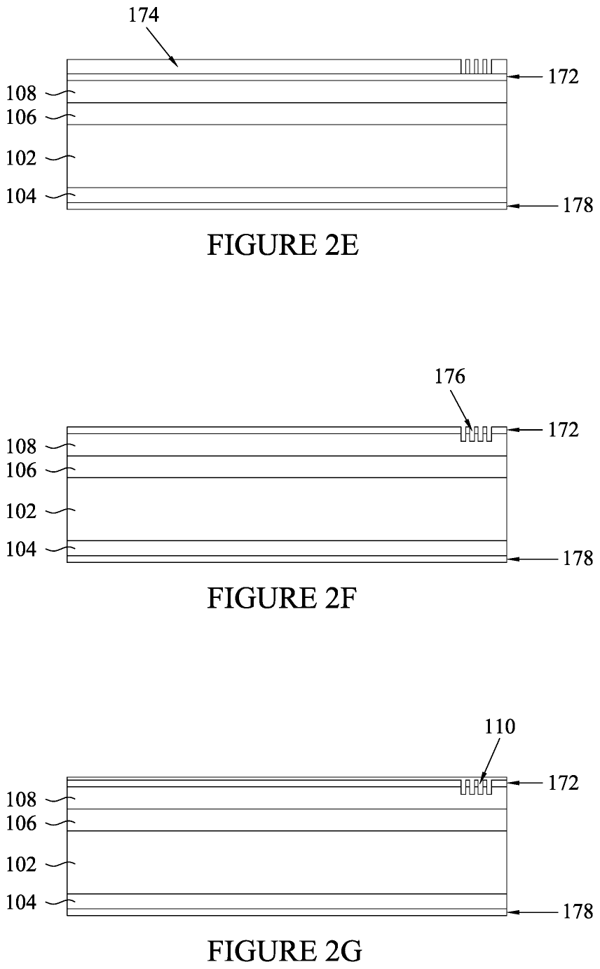

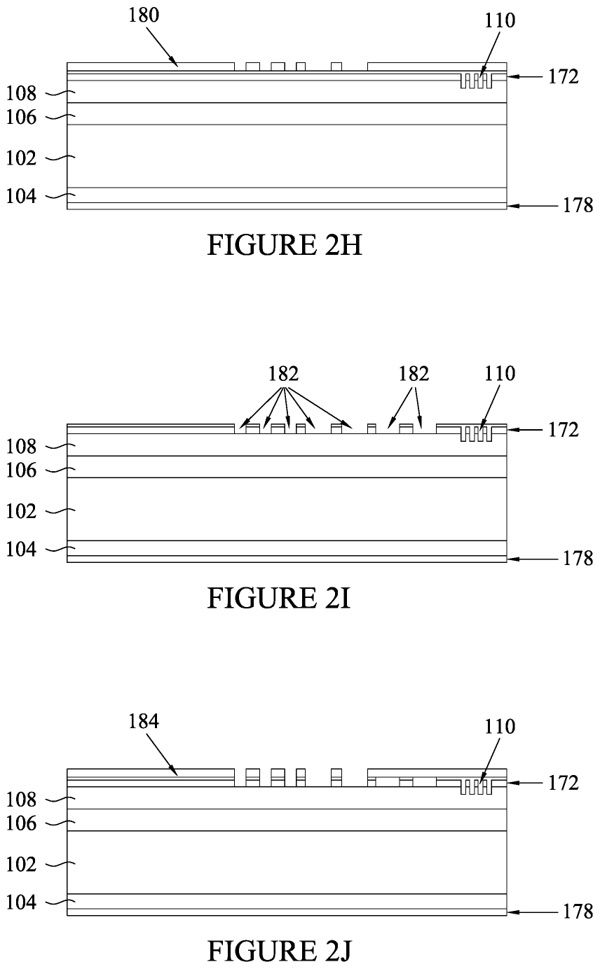

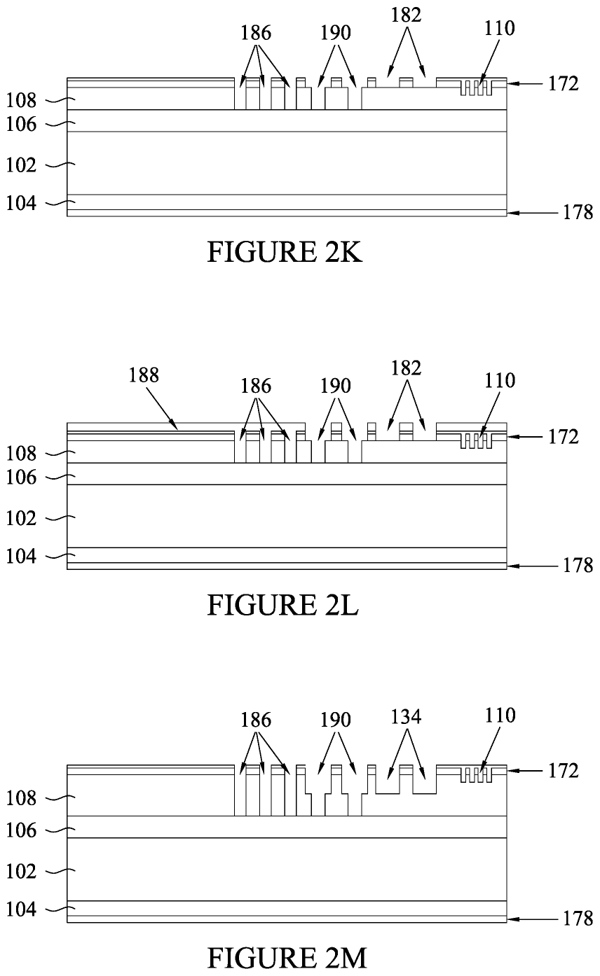

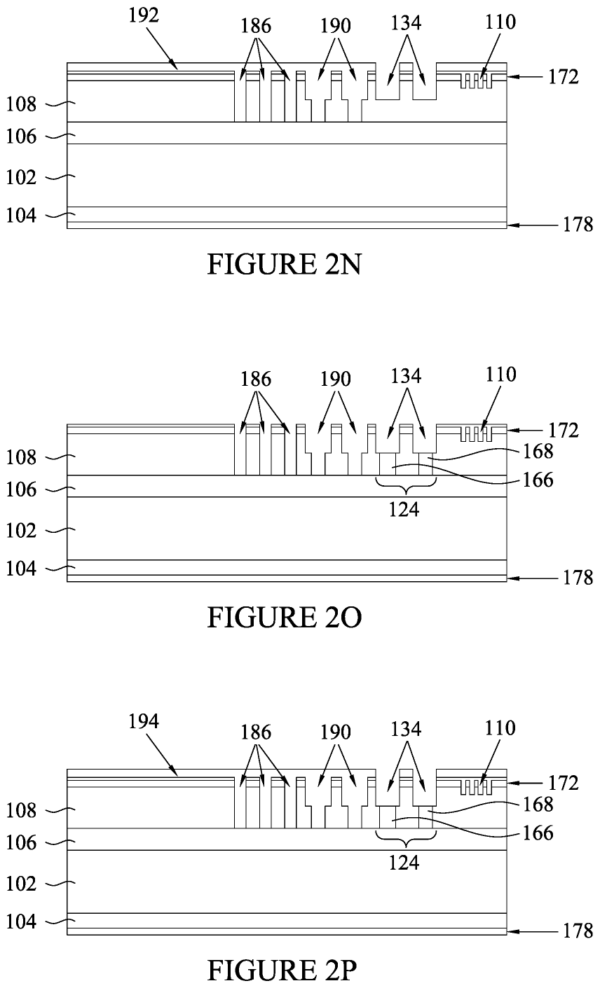

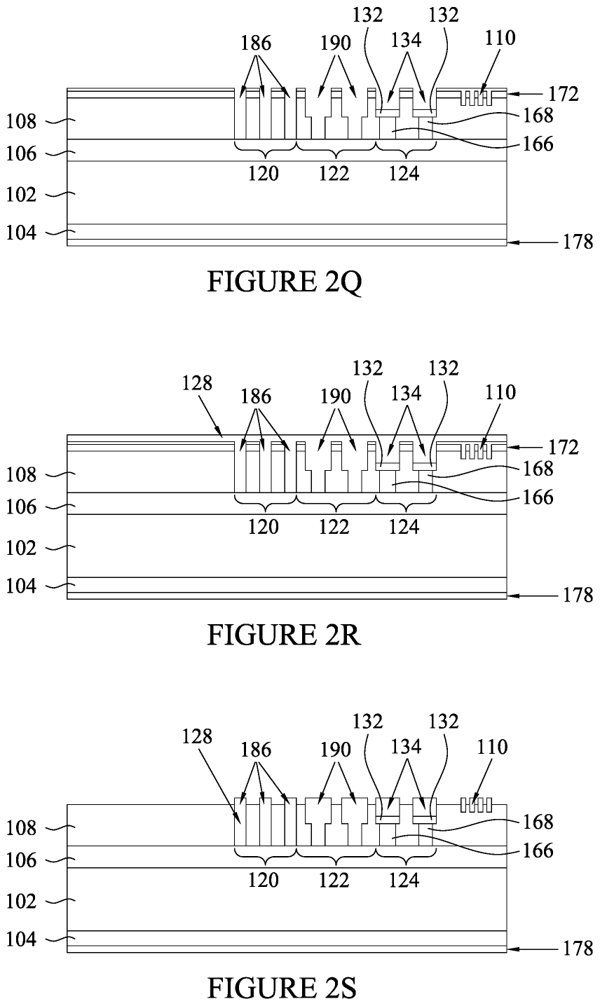

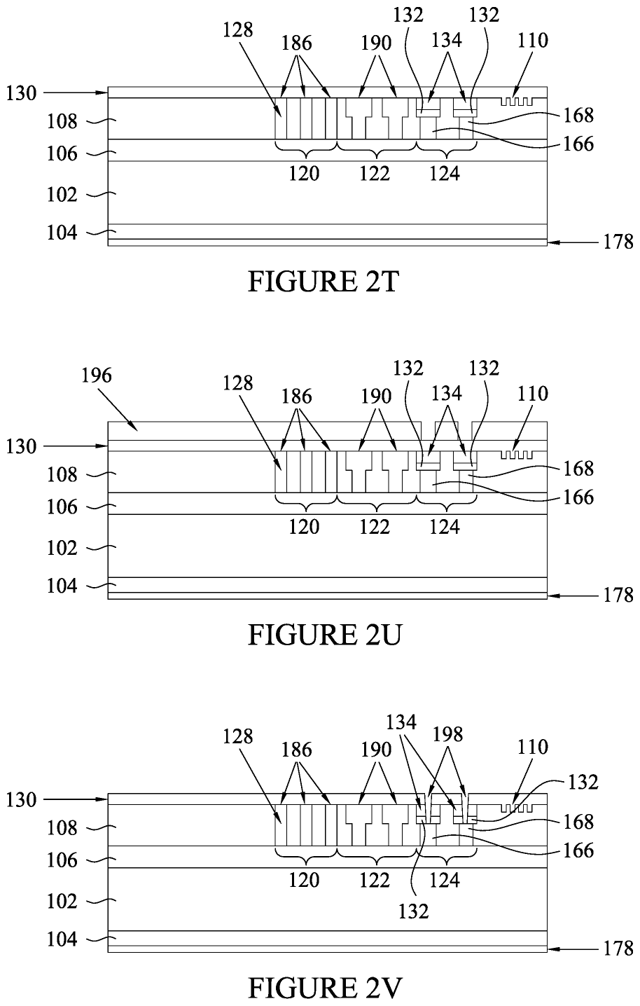

The photonic device 100 illustrated in FIG. 1 further includes an echelle grating component 118, a strip waveguide component 120, a rib to strip (R2S) waveguide component 122, and a rib waveguide component 124. Each of the aforementioned waveguide components 118-124 are suitably positioned at least partially in the first silicon layer 108. As shown in FIG. 1, a silicate glass material 128 is formed within each of the waveguide components 118-124, as described in greater detail below with respect to FIGS. 2A-2V. That is, as depicted in FIG. 1, the silicate glass material 128 may be deposited between portions of the first silicon layer 108, the combination thereof providing structure to the aforementioned waveguide components 118-124. In accordance with one example embodiment the silicate glass material 128 is a borophosphosilicate glass (BPSG) material. It will be appreciated that other suitable silicate glasses or materials providing similar optic properties and/or insulative properties may be used in other embodiments.

In accordance with some embodiments, the echelle grating waveguide component 118 may correspond to a type of diffraction grating having relatively low groove density and a groove shape that is optimized for use at high incidence angles and thus high diffraction orders. In such embodiments, the echelle grating waveguide component 118 may further include a metal component 152, e.g., an AlCu component, which may function as a mirror to reflect incident light. In accordance with further embodiments, the strip waveguide component 120 may correspond to a class of waveguides having the form of a channel running along the surface of some solid transparent host medium, e.g., a dielectric or semiconductor. The R2S waveguide component 122 may correspond to a converter component that converts a rib waveguide output to a strip waveguide input and/or a strip waveguide output to a rib waveguide input. Further, as shown in FIG. 1, the photonic device 100 includes a rib waveguide component 124, which may correspond to a waveguide in which the guiding layer may consists of the slab with a strip (or several strips) superimposed onto it. As will be appreciated by the skilled artisans, rib waveguides may provide confinement of the wave in two dimensions and near-unity confinement is possible in multi-layer rib structures. It will be appreciated that while a single rib waveguide component 124 is shown in FIG. 1, the photonic device 100 may be implemented with multiple rib waveguide components, e.g., three, four, five, etc., in accordance with desired design configurations. As such, the illustration in FIG. 1 is intended solely as one illustrative example embodiment in accordance with the subject disclosure.

As shown in FIG. 1, the photonic device 100 further includes an undoped silicate glass (“USG”) component 130 disposed on the first silicon layer 108 and the BSPG material 128. In some embodiments, the undoped silicate glass (USG) component 130 may be implemented having a thickness 147 in the range of 5,000 angstroms to 10,000 angstroms. In one embodiment, the undoped silicate glass (USG) component 130 is implanted with a thickness of 8 angstroms. However, other values and ranges are also within the scope of this disclosure.

A second etch stop layer 156 is formed on the USG component 130, as shown in FIG. 1. In accordance with some embodiments, the second etch stop layer 156 may comprise a suitable barrier material configured to protect the layers and components below from damage during subsequent etching processes. The second etch stop layer 156 may be implemented as tantalum oxide (TaO), tantalum (Ta), titanium (Ti), silicon nitride (SiN), and the like. It will be appreciated that the second etch stop layer 156 corresponds to a layer of material that has drastically different etching characteristics than the material to be etched, so as to stop or halt the etching processing of the layer deposited on the etch stop layer.

Positioned above the second etch stop layer 156 is a second topside oxide layer 154. A third topside oxide layer 158 is suitably formed on the second etch stop layer 156, as shown in FIG. 1. In accordance with some embodiments, the second topside oxide layer 154 and the third topside oxide layer 158 may comprise, for example and without limitation, for example and without limitation, non-low-k dielectric materials such as silicon oxide, silicon carbide (SiC), silicon carbo-nitride (SiCN), silicon oxy-carbo-nitride (SiOCN), or the like. A third etch stop layer 160 is depicted in FIG. 1, formed on the third topside oxide layer 158. As indicated above with respect to the first and second etch stop layers 112 and 156, the third etch stop layer 160 suitably comprises a layer of material that has drastically different etching characteristics than the material to be etched, so as to stop or halt the etching processing of the layer deposited on the etch stop layer. Accordingly, the third etch stop layer 160 may comprise, for example and without limitation tantalum oxide (TaO), tantalum (Ta), titanium (Ti), silicon nitride (SiN), and the like.

In accordance with some embodiments, the photonic device 100 of FIG. 1 further includes a fourth topside oxide layer 162 formed or deposited on the third etch stop layer 160. Such fourth topside oxide layer 162 may comprise, for example and without limitation, non-low-k dielectric materials such as silicon oxide, SiC, SiCN, SiOCN, or the like. A fourth etch stop layer 164 may be formed on the fourth topside oxide layer 162, as shown in FIG. 1. In some embodiments, the fourth etch stop layer 164 may comprise, for example and without limitation tantalum oxide (TaO), tantalum (Ta), titanium (Ti), silicon nitride (SiN), and the like. In varying embodiments disclosed herein, the first, second, third, and fourth topside oxide layers 106, 154, 158, and 162 may comprise the same or different oxide materials. In some embodiments, the aforementioned oxide layers 106, 154, 158, and 162 may comprise the same oxide material, deposited or formed at different times or stages of the fabrication of the photonic device 100.

In FIG. 1, the rib waveguide component 124 includes rib contact holes 134 extending a preselected distance into the first silicon layer 108, a contact etch stop layer (CESL) 132 formed on a bottom of the rib contact holes 134, rib contacts 138 formed of a suitably conductive material extending through the rib contact holes 134, a rib N+ doped component 166, and a P+ doped component 168 positioned below the contact etch stop layer (CESL) 132 within the first silicon layer 108. As illustrated in FIG. 1, the each contact hole 134 includes the aforementioned silicate glass material 128. In accordance with some embodiments, the thickness or depth of the contact etch stop layer (CESL) 132 is 5% or greater than the depth 170 of the contact hole 134.

As will be appreciated, the doping to form components 166 and 168 may be done, for example, by ion implantation. Briefly, an ion implanter is used to implant atoms into a silicon crystal lattice, modifying the conductivity of the lattice in the implanted location. An ion implanter generally includes an ion source, a beam line, and a process chamber. The ion source produces the desired ions (here, for example, Co, Ti, Ni, Pt, or Pb, depending on desired N- or P-type electrode). The beam line organizes the ions into a beam having high purity in terms of ion mass, energy, and species. The ion beam is then used to irradiate the wafer substrate in a process chamber. The ion beam strikes the exposed regions on the wafer substrate, and the ions can be implanted into the substrate as dopants at desired depths. Alternatively, the substrate can be partially etched, followed by blanket deposition of a metal, followed by annealing in which the metal reacts with the underlying exposed silicon. Unreacted metal can then be removed, for example with a selective etch process. As illustrated in FIG. 1, the contact holes 134 include a contact hole depth 170 of between 8,000 to 14,000 angstroms into the first silicon layer 108. In other embodiments, the contact hole depth 170 is in the range of between 9,000 to 12,000 angstroms into the first silicon layer 108. However, other values and ranges are also within the scope of this disclosure. It will further be appreciated that the contacts 138 extend through the contact etch stop layer (CESL) 132 to contact respective first rib doped components 166 and 168.

In accordance with some embodiments, the contacts 138 are electrically contacting metal components 140 formed partially in the second and third topside oxide layers 154 and 158, as shown in FIG. 1. According to such an embodiment, each metal component 140, which may provide similar function to a via, is in electrical contact with a corresponding bump pad 142. It will be appreciated that the metal components 140 may be implemented as, for example and without limitation, any suitable conductive material including, for example and without limitation, a suitable conductive metal including, for example and without limitation, copper, aluminum, iron, alloys thereof. Further, some embodiments disclosed herein may utilize a bump pad 142 comprised of, for example and without limitation, Al, Fe, Cu, Al—Cu, alloys thereof, or any other suitable material, as will be appreciated by the skilled artisan. As shown in FIG. 1, each of the bump pads 142 are suitably disposed through the fourth topside oxide layer 162. Subsequent fabrication (not shown) may include the addition of one or more solder bumps comprising lead-alloy solders, lead-free solders, flux-core solder, silver-alloy solders, or the like.

As illustrated in FIG. 1, the photonic device 100 further includes a reflection device trench structure 116, formed in the substrate 102. The trench structure 116 includes a first oblique plane 135, a bottom plane 136, and a second oblique plane 137. As shown in FIG. 1, the first and second oblique planes 135 and 137 are positioned opposite each other, separated by the bottom plane 136. It will be appreciated that the length of the bottom plane 136 may vary in accordance with design requirements. Further, as shown in FIG. 1, the trench structure 116 may vary in size, such that it may extend under the echelle grating component 118, or alternatively, be positioned in front of the echelle grating component 118. As shown in FIG. 1, the reflection device 114 is positioned relatively parallel to the first oblique plane 135, i.e., having the same angle relative to the waveguide components 118-124. In accordance with one embodiment, the photonic device 100 of FIG. 1 may utilize an external light source (not shown). In such embodiments, the light source may be implemented as, for example and without limitation, a laser (e.g., a III-V laser), an optical fiber, an exterior light source, a reflected light, or the like, directing light to the reflection device 114. In some embodiments, the light source may produce light in the wavelength range of 200 nm to 1300 nm, and in some embodiments in the range of 300 nm to 1200 nm. However, other values and ranges are also within the scope of this disclosure.

Turning now to FIGS. 2A-2V, there are shown a series of intermediate stages of fabrication optical components of the photonic device 100 of FIG. 1 in accordance with some embodiments. The patterning of a layer may employ any suitable patterning technique such as a photolithographic patterning technique using deposition of a photoresist layer and selective exposure via a photomask to visible light, ultraviolet light, deep ultraviolet light (i.e., DUV lithography), extreme ultraviolet light (i.e. EUV lithography), or so forth, followed by development of the exposed photoresist and subsequent etching, deposition or other process steps laterally delineated by the developed photoresist. In other embodiments, patterning of an electron-sensitive resist layer may be by way of electron beam exposure (electron beam lithography, i.e., e-beam lithography). The skilled artisan will appreciate that the foregoing are merely illustrative examples.

As shown in FIG. 2A, a substrate 102 is formed having a backside oxide layer 104. In some embodiments, the backside oxide layer 104 includes a polyimide layer 178 formed on a surface thereof opposite the surface contacting the substrate 102. In accordance with one embodiment, the substrate 102 is an SOI substrate, as described above with respect to FIG. 1.

In FIG. 2B, a first topside oxide layer 106 is formed on the substrate 102. As shown in FIG. 2B, the first topside oxide layer 106 is deposited on the top side of the substrate opposite the side of the substrate 102 to which the bottom oxide layer 104 is attached. As referenced above, the first topside oxide layer 106 may comprise, for example and without limitation, non-low-k dielectric materials such as silicon oxide, silicon carbide (SiC), silicon carbo-nitride (SiCN), silicon oxy-carbo-nitride (SiOCN), or the like. In accordance with some embodiments, formation of the first topside oxide layer 106 may be accomplished via any suitable deposition or layer processes, including, for example and without limitation, deposited by, for example, chemical vapor deposition (CVD), physical vapor deposition (PVD), atomic layer deposition (ALD), sputtering, another deposition process, or any suitable combination thereof. In some embodiments, chemical-mechanical polishing (CMP) may be performed after deposition of the first topside layer 106, resulting in the planar surface shown in FIG. 2B.

A first silicon layer 108 is then deposited on the first topside oxide layer 106, as shown in FIG. 2C. Suitable methods of forming the first silicon layer 108 may include, for example and without limitation, chemical vapor deposition (CVD), physical vapor deposition (PVD), atomic layer deposition (ALD), sputtering, another deposition process, or any suitable combination thereof. In some embodiments, chemical-mechanical polishing (CMP) may be performed after deposition of the first silicon layer 108, resulting in the planar surface shown in FIG. 2C. The first silicon layer 108 may comprise a silicon, for example and without limitation, in the form of crystalline Si or polycrystalline Si. In accordance with some embodiments, the first silicon layer 108 may be implemented with a thickness in the range of 1 um to 5 um, and in some embodiments, may have a thickness of 3 um. However, other values and ranges are also within the scope of this disclosure.

A hard mask 172 is then formed on the first silicon layer 108, as depicted in FIG. 2D. In accordance with some embodiments, the hard mask 172 comprises layers of oxide material with a polyimide layer disposed therebetween. In some embodiments, a first oxide material is deposited, followed by CMP, after which the polyimide material is deposited. After CMP is performed on the polyimide material, a second oxide material is deposited, after which CMP is performed, resulting in the intermediate stage of fabrication shown in FIG. 2D. As discussed above, various deposition methods may be used to produce the layers of the hard mask 172, as will be appreciated by the skilled artisan.

A photoresist 174 is then deposited and patterned on the hard mask 172, as illustrated in FIG. 2E. In some embodiments, the photoresist 174 is applied to the hard mask 172, after which portions of the photoresist 174 are developed by exposure from a suitable light source to form a pattern thereon. The unexposed portions are then removed, resulting in the patterned photoresist 174 shown in FIG. 2E. Etching is then performed to remove those portions of the hard mask 172 and/or underlying first silicon layer 108 to form distributed Bragg reflector (DBR) holes 176. Suitable removal processes include, for example and without limitation, an etching process implemented as a dry etching process, a RIE process, a wet etching process, some other etching process, or a combination of the foregoing. In accordance with some embodiments, the DBR holes 176 may be implemented with a depth in the range of 0.01 um to 0.6 um, and in some embodiments, the depth of the DBR holes 176 may be less than or equal to 0.4 um. However, other values and ranges are also within the scope of this disclosure. FIG. 2F provides an illustration of the photonic device 100 after formation of the DBR holes 176. The DBR holes 176 are then filled with a suitable material having a desired refractive index for forming the DBR 110, as shown in FIG. 2G. In accordance with some embodiments, the DBR holes 176 are filled with a silicate glass, an oxide material, including, for example and without limitation, undoped silicate glass, BPSG glass, or the like.

In FIG. 2H, a photoresist 180 is then deposited and patterned on the hard mask 172. In some embodiments, the photoresist 180 is applied to the hard mask 172, after which portions of the photoresist 180 are developed by exposure from a suitable light source to form a pattern thereon. The unexposed portions are then removed, resulting in the patterned photoresist 180 shown in FIG. 2H. Etching is then performed to remove those portions of the hard mask 186 and/or underlying first silicon layer 108 to form strip and rib hard mask holes 182, as illustrated in FIG. 2I. Suitable removal processes include, for example and without limitation, an etching process implemented as a dry etching process, a RIE process, a wet etching process, some other etching process, or a combination of the foregoing.

A photoresist 184 is then deposited and patterned on the hard mask 172, as shown in FIG. 2J. In some embodiments, the photoresist 184 is applied to the hard mask 172, after which portions of the photoresist 184 are developed by exposure from a suitable light source to form a pattern thereon. The unexposed portions are then removed, resulting in the patterned photoresist 184 shown in FIG. 2J. Etching is then performed to remove those portions of the first silicon layer 108 to enable formation of strip holes 186 and a portion of the R2S holes 190, as illustrated in FIG. 2K. Suitable removal processes include, for example and without limitation, an etching process implemented as a dry etching process, a RIE process, a wet etching process, some other etching process, or a combination of the foregoing.

In FIG. 2L, a photoresist 188 is deposited and patterned on the hard mask 172 and in a portion of the strip holes 186. As illustrated in FIG. 2L, the photoresist is further patterned to enable formation of the rib waveguide component 124. The photoresist 188 is then exposed, and the unexposed portions of the photoresist 188 are removed, resulting in the intermediate fabrication stage of the photonic device 100 shown in FIG. 2L. Thereafter, etching is then performed to remove those portions of the first silicon layer 108 to enable formation of R2S holes 190 and the rib contact holes 134, as illustrated in FIG. 2M. Suitable etching processes include, for example and without limitation, a dry etching process, a RIE process, a wet etching process, some other etching process, or a combination of the foregoing.

A photoresist 192 is then formed and patterned on the photonic device 100, as shown in FIG. 2N. Accordingly, photoresist 192 is deposited into the strip holes 186, and the R2S holes 190. Doping is then performed on the silicon layer 108 exposed in the rib contact holes 134. As shown in FIG. 2O, a rib N+ doped component 166, and a rib P+ doped component 168 are formed within the first silicon layer 108 in the rib contact holes 134. As will be appreciated, the doping to form components 166 and 168 may be done, for example, by ion implantation. As discussed above, an ion implanter is used to implant atoms into a silicon crystal lattice, modifying the conductivity of the lattice in the implanted location. An ion implanter generally includes an ion source, a beam line, and a process chamber. The ion source produces the desired ions (here, for example, Co, Ti, Ni, Pt, or Pb, depending on desired N- or P-type electrode). The beam line organizes the ions into a beam having high purity in terms of ion mass, energy, and species. The ion beam is then used to irradiate the wafer substrate in a process chamber. The ion beam strikes the exposed regions on the wafer substrate, and the ions can be implanted into the substrate as dopants at desired depths. Alternatively, the substrate can be partially etched, followed by blanket deposition of a metal, followed by annealing in which the metal reacts with the underlying exposed silicon. Unreacted metal can then be removed, for example with a selective etch process.

In FIG. 2P, a photoresist 194 is then deposited into the strip holes 186, and the R2S holes 190, thereby exposing the rib contact holes 134. Thereafter, a contact etch stop layer (CESL) 132 is deposited in the rib contact holes 134 and, as shown in FIG. 2Q, positioned above respective doped components 166-168. In accordance with some embodiments, the contact etch stop layer (CESL) 132 suitably comprises a layer of material that has drastically different etching characteristics than the material to be etched, so as to stop or halt the etching processing of the layer deposited on the etch stop layer. Accordingly, the contact etch stop layer (CESL) 132 may comprise, for example and without limitation tantalum oxide (TaO), tantalum (Ta), titanium (Ti), silicon nitride (SiN), and the like.

A silicate glass material 128 is then deposited on the photonic device 100, as shown in FIG. 2R. As indicated above, the silicate glass material 128 is suitably formed in the strip holes 186, the R2S holes 190, and the rib contact holes 134. Thereafter, CMP and polyimide etching (i.e., removal of the hard mask 172) is performed, as depicted in FIG. 2S. Undoped silicate glass 130 is then deposited, as shown in FIG. 2T. In accordance with some embodiments, the undoped silicate glass (USG) component 130 may be implemented having a thickness in the range of 5000 angstroms to 10,000 angstroms. In one embodiment, the undoped silicate glass (USG) component 130 is implanted with a thickness of 8 angstroms. However, other values and ranges are also within the scope of this disclosure.

In FIG. 2U, a photoresist 196 is deposited and patterned on the undoped silicate glass (USG) component 130. As shown, the photoresist 196 is suitably patterned to allow for subsequent formation of rib contact cavities 198 located within the rib contact holes 134. Etching is then performed to create the rib contact cavities 198, as shown in FIG. 2U. In accordance with some embodiments, CMP may also be performed to planarize the undoped silicate glass (USG) component 130. Thereafter, as will be appreciated, subsequent formation of the photonic device 100 may be performed, e.g., forming the trench structure 116 and reflection device 114, forming the rib contacts 138, interlayer dielectric fabrication, the metal components 140, the bump pad 142, etc. Additionally, formation of the reflection device trench structure 116 may be performed in accordance with some embodiments. It will be appreciated that while shown and described as being performed after waveguide formation (i.e., FIGS. 2A-2U), the reflection device trench structure 116 may be formed prior to the other photonic device components, and the description provided herein is intended solely as one example formation strategy.

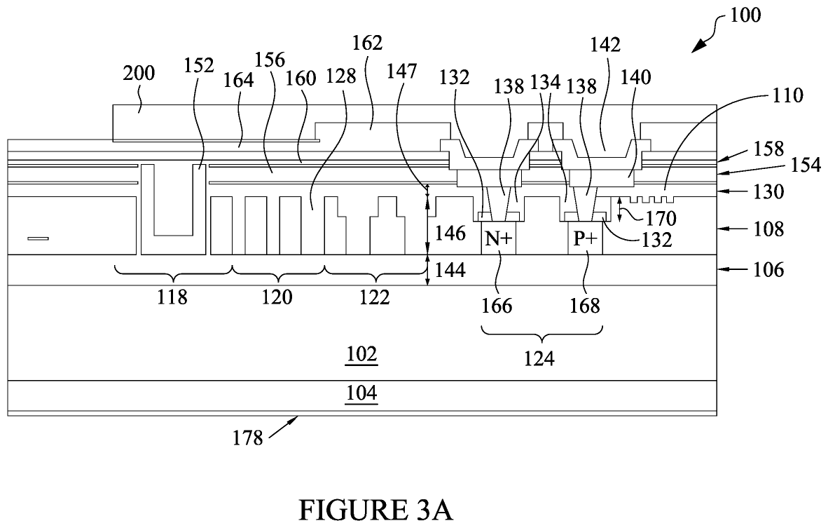

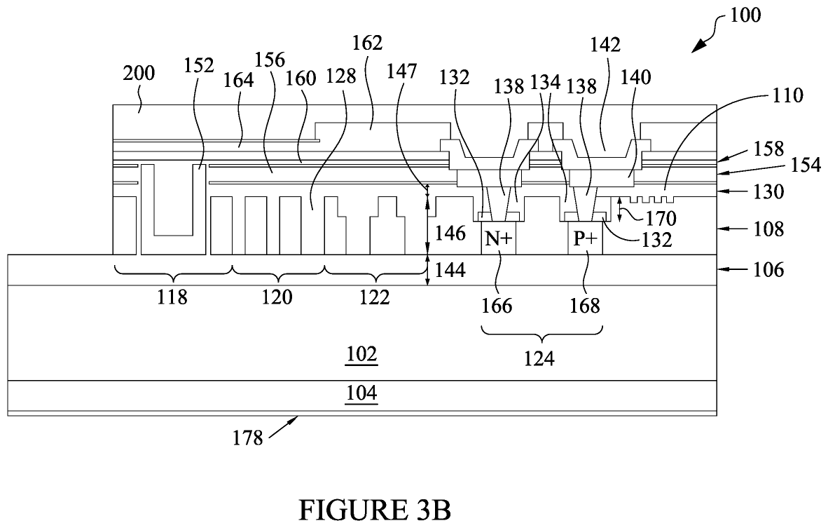

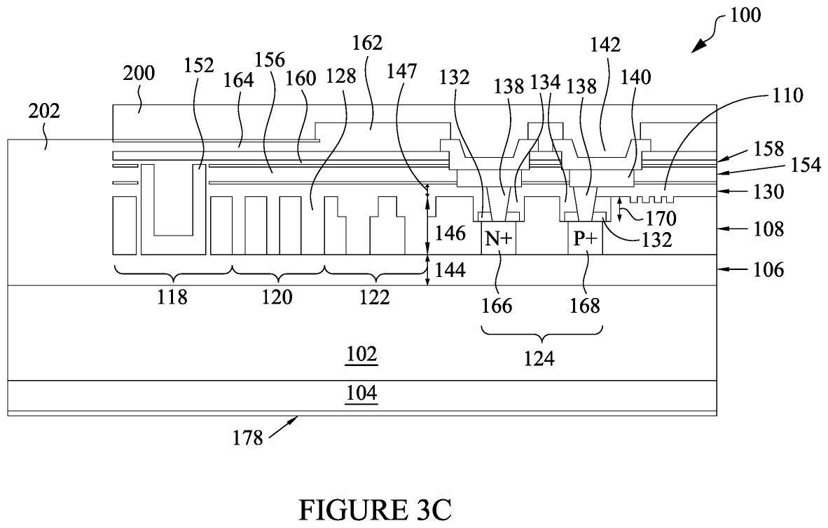

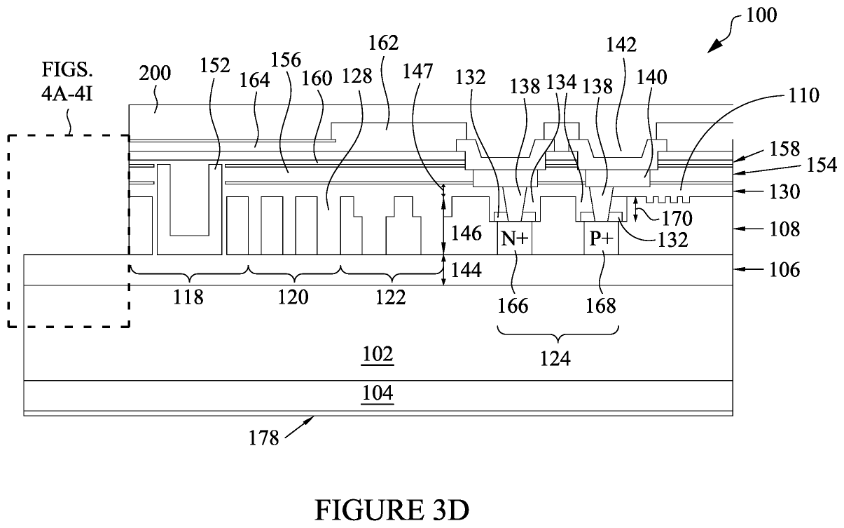

Turning now to FIGS. 3A-3D, there are shown close-up cross-sectional views of fabrication stages of the portion of the photonic device 100 wherein the reflection device 114 and reflection device trench structure 116 are located in accordance with some embodiments. As shown in FIG. 3A, a photoresist 200 is deposited and patterned on the photonic device 100 to protect portions of the photonic device 100 from subsequent processing. That is, a portion located adjacent to the Echelle grating component 118 is left exposed after patterning of the photoresist 200. In FIG. 3B, an initial etching operation is performed to remove portions of topside oxide layers 130, 154, 158, 162 and the first silicon layer 108, thereby exposing the first topside oxide layer 106.

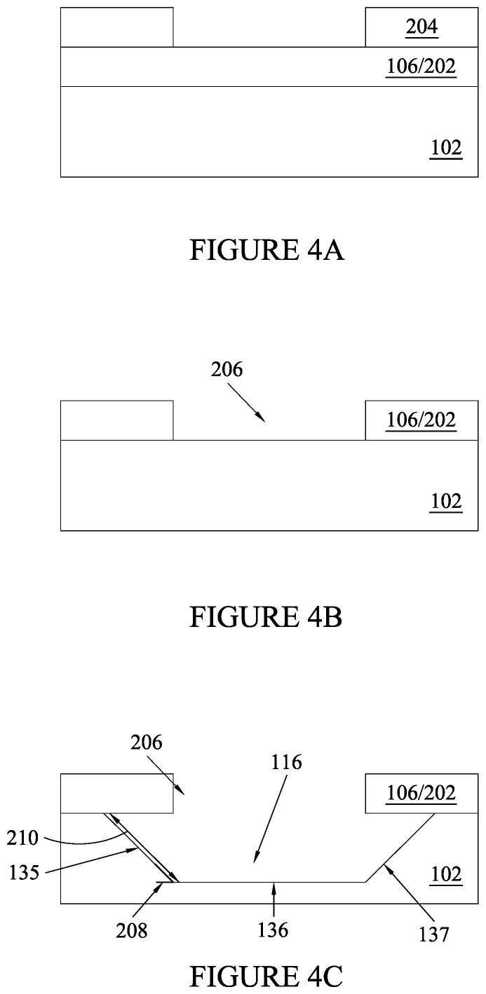

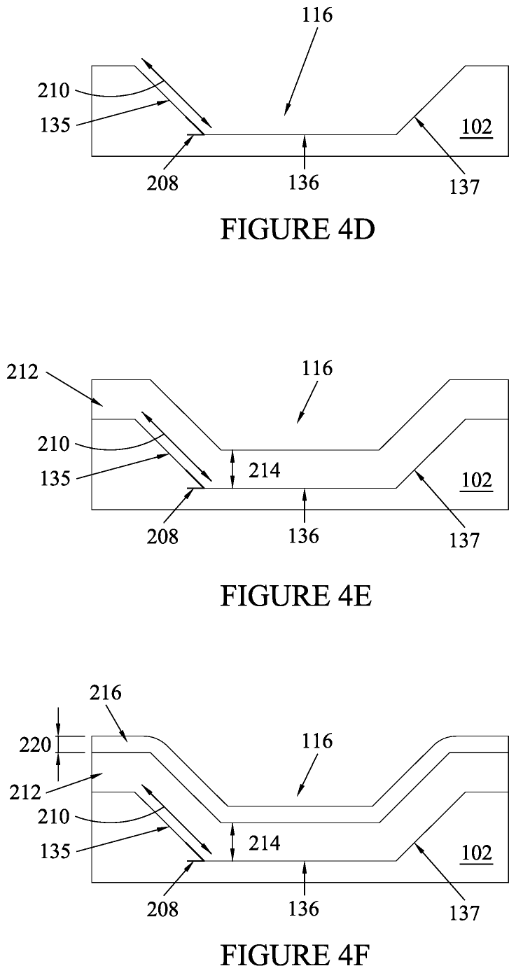

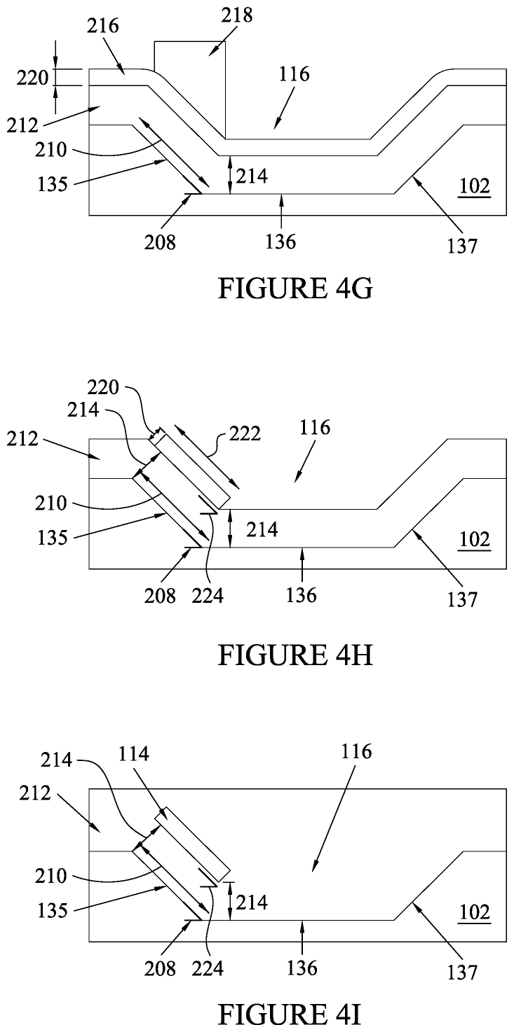

An oxide 202 is then deposited and CMP may be performed on the photonic device 100, as shown in FIG. 3C. In accordance with one embodiment, the oxide 202 may comprise, for example and without limitation, non-low-k dielectric materials such as silicon oxide, silicon carbide (SiC), silicon carbo-nitride (SiCN), silicon oxy-carbo-nitride (SiOCN), or the like. In some embodiments, the oxide 202 may comprise the same material as the first topside oxide layer 106. Etching is then performed, as shown in FIG. 3D, leaving a portion of the oxide 202 and/or first topside oxide layer 106 in place on the substrate 102. Further processing is described below, with respect to FIGS. 4A-4I.

Turning now to FIGS. 4A-4I, there are shown stages of fabrication of the reflection device 114 and reflection device trench structure 116 in accordance with some embodiments. As will be appreciated, the fabrication stages shown in FIGS. 4A-4I continue forming the photonic device 100 depicted in FIG. 3D. In FIG. 4A, there is shown a close-up cross-sectional view of the portions of the substrate 102 and first topside oxide layer 106. In some embodiments, the first topside oxide layer 106 and oxide 202 are utilized as a hard mask to enable subsequent trench formation, as will be appreciated. Thus, in FIG. 4A, a photoresist 204 is deposited and patterned on the first top oxide layer 106/oxide 202. A hard mask opening 206 is then formed through the first top oxide layer 106/oxide 202, as shown in FIG. 4B.

As shown in FIG. 4C, etching is performed through the hard mask opening 206 into the substrate 102, thereby forming the reflection device trench structure 116. Accordingly, FIG. 4C provides an illustration of the formation of the first oblique plane 135, the bottom plane 136, and the second oblique plane 137. Suitable etching processes may include, for example and without limitation, an etching process implemented as a dry etching process, a RIE process, a wet etching process, some other etching process, or a combination of the foregoing. In some embodiments, wet etching is used to form the planes 135-137 of the trench structure 116. As shown in FIG. 4C, the first oblique plane 135 is angled with respect to the bottom plane 136. The first oblique plane angle 208, as shown in FIG. 4C, may range from about 0° to 55° and, in some embodiments, in the range of about 0° to 45°. However, other values and ranges are also within the scope of this disclosure. In accordance with some embodiments, the first oblique plane 135 may have a length 210 in the range of about 1 um to 20 um, and in some embodiments, may be greater than or equal to 10 um. However, other values and ranges are also within the scope of this disclosure. In such embodiments, the length 210 of the first oblique plane 135 is greater than the length of the reflection device 114.

In FIG. 4D, the remaining first topside oxide layer 106 and/or oxide 202, i.e., the hard mask, is removed via etching or other suitable removal process. Accordingly, as illustrated in FIG. 4D, the reflection device trench structure 116 is accessible in the substrate 102. In FIG. 4E, an oxide layer 212 is deposited for profile transfer. As shown in FIG. 4E, the oxide layer 212 is deposited on the substrate 102, the first oblique plane 135, the bottom plane 136, and the second oblique plane 137. In accordance to some embodiments, the oxide layer 212 is deposited to as to form a layer on the planes 135-137, as shown. It will be appreciated that in accordance with some embodiments, the thickness of the oxide layer 212 is configured to reflect the position of the reflection device 114. In some embodiments, the oxide layer 212 is deposited with a thickness 214 in the range of about 1 um to 10 um, and in some embodiments, the thickness 214 of the oxide layer 212 is greater than or equal to 7 um. However, other values and ranges are also within the scope of this disclosure.

In FIG. 4F, a reflection layer 216 is deposited on the oxide layer 212. The reflection layer 216 may be deposited via any suitable means including, for example and without limitation, chemical vapor deposition (CVD), physical vapor deposition (PVD), atomic layer deposition (ALD), sputtering, another deposition process, or any suitable combination thereof. The reflection layer 216 may comprise, for example and without limitation, Al, AlCu, AlSiCu, AlSi, AlCr, or other suitable reflect metal, metal alloy, or the like. The reflection layer 216 may be formed with a thickness 220 in the range of about 1 um to 7 um, and in some embodiments, within the range of about 3 um to 5 um. However, other values and ranges are also within the scope of this disclosure. In accordance with other embodiments, the reflection layer 216 may comprise a plurality of layers of different reflective materials or coatings. Thus, in such embodiments, a metal layer may be deposited followed by one or more high reflection coatings such as, for example and without limitation, SiO2/TiO2, AlAs/GaAs, AlN/GaN, and the like. In accordance with some embodiments, the number of layers of high reflection material is greater than or equal to three layers, and may be greater than four layers of high reflection material.

FIG. 4G illustrates a subsequent stage of manufacturing of the photonic device 100 in accordance with some embodiments. As shown in FIG. 4G, a photoresist 218 is deposited and patterned on the reflection layer 216. That is, a photoresist layer 218 is formed on the reflection layer 216 and selective exposure via a photomask to visible light, ultraviolet light, deep ultraviolet light (i.e., DUV lithography), extreme ultraviolet light (i.e., EUV lithography), or so forth, followed by development of the exposed photoresist is performed. Thereafter, the unexposed portions of the photoresist material are removed, resulting in the photoresist 218 illustrated in FIG. 4G on the portion of the reflection layer 216 to be utilized as the reflection device 114.

As shown in FIG. 4H, etching is performed to remove portions of the reflection layer 216 unprotected by the photoresist 218, whereafter the photoresist is removed. FIG. 4H thereby illustrates the reflection device 114 positioned adjacent to the first oblique plane 135 on the oxide 212. As shown in FIG. 4H, the reflection device 114 is positioned the thickness 214 of the oxide layer 212 from the first oblique plane 135 at reflection device angle 224. The reflection device angle 224, as shown in FIG. 4H, may range from about 0° to 55° and, in some embodiments, in the range of about 0° to 45°. However, other values and ranges are also within the scope of this disclosure. In accordance with some embodiments, the reflection device 114 may be implemented with a length 222 corresponding to the length of the first oblique plane 135. Thus, in such embodiments, the length 222 of the reflection device 114 may be implemented with a length 222 in the range of about 1 um to 20 um, and in some embodiments, may be greater than or equal to 10 um. However, other values and ranges are also within the scope of this disclosure. In accordance with some embodiments, the length 210 of the first oblique plane 135 is greater than the length 224 of the reflection device 114. Thereafter, additional oxide material is deposited on the oxide layer 212 and the reflection device 114 filling the reflection device trench structure 116, as illustrated in FIG. 4I.

Turning now to FIGS. 5A-5C, there are shown varying implementations of the reflection device 114 in a photonic device 100 in accordance with some embodiments. As shown in the embodiment of FIG. 5A, the reflection device 114 is illustrated in the form of a single layer of a solid material such as metal, as previously described above with respect to FIGS. 4A-4I. FIG. 5B provides an embodiment in which the reflection device 226 is formed from a plurality of high reflection coatings. FIG. 5C provides an embodiment in which a plurality of reflection devices 114 are positioned in respective reflection device trench structures 116 of the photonic device 100. This may be useful for reflecting light over a larger area, or light from multiple light sources, or light having different wavelengths. It will be appreciated that while shown with two reflection devices 114, the photonic device 100 may be implemented with any suitable number of reflection devices 114, including, for example and without limitation, 1, 2, 3, 4, 5, etc., in combination with a corresponding number of associated reflection device trench structures 116.

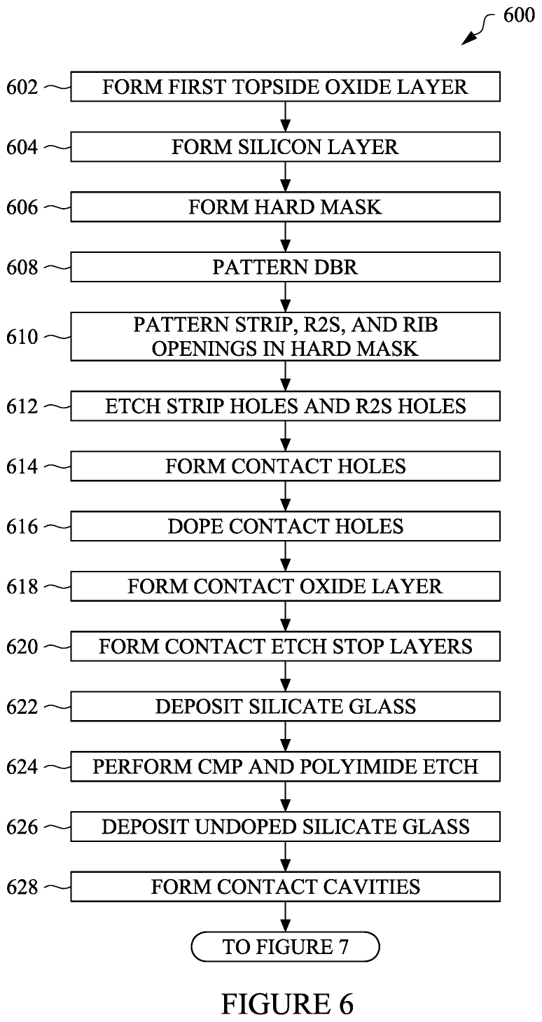

Referring now to FIG. 6, there is shown a flowchart 600 illustrating a method of fabricating a photonic device structure in accordance with one exemplary embodiment. As shown in FIG. 6, the method begins at step 602, whereupon a first topside oxide layer 106 is formed on a substrate 102, as shown in FIG. 2B. In some embodiments, the substrate 102 may be an SOI (Silicon on Insulator) substrate. A silicon layer 108 is then formed on the first topside oxide layer 106 at step 604. FIG. 2C provides an illustrative example of the deposition of the silicon layer 108. At step 606, a hard mask 172 is formed on the silicon layer 108, as illustrated in FIG. 2D.

A distributed Bragg reflector 110 is then patterned in the hard mask 172 and the silicon layer 108 at step 608. FIGS. 2E and 2F, as discussed above, provide illustrative examples of the processes performed at step 608. At step 610, strip, R2S, and rib hard mask openings 182 are patterned, as shown in FIGS. 2G-2I. Thereafter, at step 612 etching is performed to remove portions of the silicon layer 108 to form the strip holes 186 and R2S holes 190. FIGS. 2J-2K provide illustrations of the formation of the strip holes 186 and R2S holes 190 in accordance with some embodiments.

At step 614, rib contact holes 134 corresponding to a rib waveguide component 124 are formed in silicon layer 108. As illustrated in FIGS. 2L-2M, a photoresist 188 may be deposited and patterned on the silicon layer 108, followed by etching to remove portions of the silicon layer 108, thereby defining the rib contact holes 134. At step 616, the silicon layer 108 of the first contact holes 134 is doped, as shown in FIGS. 2N-2O. As discussed above, N+ component 166 and P+ component 168 are formed in the first contact holes 134 of the rib waveguide component 124.

Thereafter, at step 620, a contact etch stop layer (CESL) 132 is formed in the contact holes 134 above the doped components 166 and 168. Formation of the contact etch stop layer (CESL) 132 may include patterning (application, development, etc.) of a photoresist 194 as shown in FIG. 2P. As illustrated in FIG. 2Q, the formation of the contact etch stop layer (CESL) 132 may result in contact etch stop layer (CESL) 132 material deposited on the doped components 166 and 168.

At step 622, a silicate glass 128 is deposited, filling in the contact holes 134, as illustrated in FIG. 2R. Thereafter, at step 624 CMP and polyimide etching (i.e., removal of the hard mask 172) is performed, as depicted in FIG. 2S. At step 626, a layer of undoped silicate glass 130 is deposited on the silicon layer 108, as illustrated in FIG. 2T. At step 628, contact cavities 198 are formed in the contact holes 134, as shown in FIGS. 2U-2V. As shown in FIG. 2V, the contact cavities 198 extend through the undoped silicate glass 130, the silicate glass 128, and the contact etch stop layer 132, allowing for subsequent formation of contacts 138, as illustrated in FIG. 1.

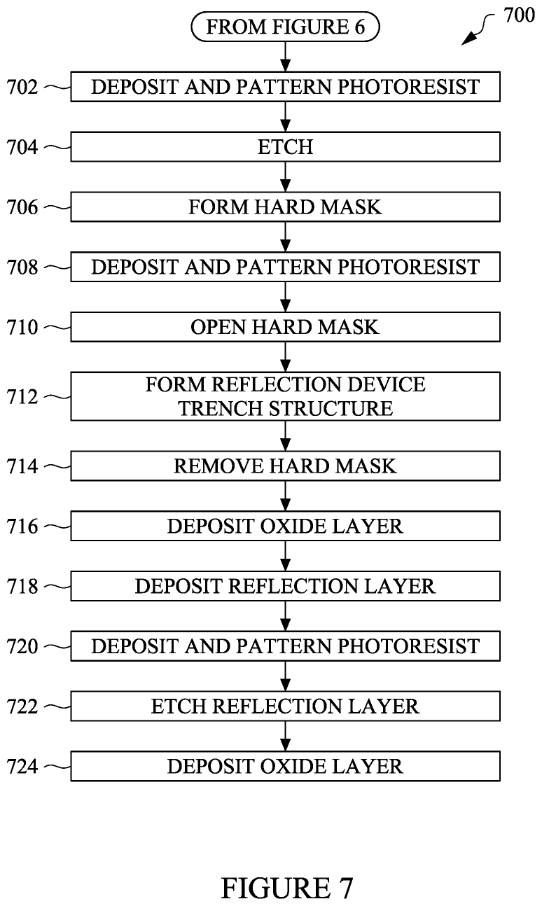

Operations then proceed to FIG. 7, whereupon the reflection device 114 and reflection device trench structure 116 are formed on the photonic device 100 in accordance with one exemplary embodiment. The method of FIG. 7 begins at step 702, whereupon a photoresist 200 is deposited and patterned on the photonic device 100 to protect portions of the photonic device 100 from subsequent processing. That is, as shown in FIG. 3A, a portion located adjacent to the Echelle grating component 118 is left exposed after patterning of the photoresist 200. At step 704, etching is performed to remove the unprotected portions of the photonic device 100, as illustrated in FIG. 3B. In accordance with some embodiments, portions of topside oxide layers 130, 154, 158, 162 and the first silicon layer 108, thereby exposing the first topside oxide layer 106. Alternatively, the etching performed at step 704 may result in the exposure of the substrate 102, i.e., the removal of all layers above that portion of the substrate 102 uncovered by the aforementioned photoresist 200.

At step 706, a hard mask of oxide 202 is formed by deposition and CMP may on the photonic device 100, as shown in FIG. 3C. In accordance with some embodiments, the addition of the oxide material 202 on the first topside oxide layer 106 may assist in the formation of a hard mask, i.e., thickening the oxide to allow for subsequent etching processes of the substrate 102, as discussed below. At step 708, a photoresist 204 is deposited and patterned on the hard mask, i.e., the combination of oxides 106 and 202, to allow for subsequent opening of the aforementioned hard mask. FIG. 4A provides an illustrative example of the processes performed at step 708.

Operations then proceed to step 710, whereupon a hard mask opening 206 is formed, exposing the substrate 102, as shown in FIG. 4B. At step 712, a reflection device trench structure 116 is formed in the substrate 102, as illustrated in FIG. 4C. In accordance with some embodiments, etching is performed, e.g., wet etching, through the hard mask opening 206, to form the first oblique plane 135, the bottom plane 136, and the second oblique plane 137 of the reflection device trench structure 116 in the substrate 102. While referenced above as using a wet etching process, the skilled artisan will appreciate that other suitable methods may be used to form the trench structure 116 including, for example and without limitation, a dry etching process, a RIE process, some other etching process, or a combination of the foregoing. As discussed above and illustrated in FIG. 4C, the first oblique plane 135 is angled with respect to the bottom plane 136 at a first oblique plane angle 208, ranging from about 0° to 55° and, in some embodiments, in the range of about 0° to 45°. However, other values and ranges are also within the scope of this disclosure. Further, in accordance with some embodiments, the first oblique plane 135 may have a length 210 in the range of about 1 um to 20 um, and in some embodiments, may be greater than or equal to 10 um. However, other values and ranges are also within the scope of this disclosure.

At step 714, the remaining hard mask material is removed via etching or other suitable removal process, as illustrated in FIG. 4C. At step 716, an oxide layer 212 is deposited for profile transfer in the reflection device trench structure 116, as shown in FIG. 4E. In accordance with some embodiments, the oxide layer 212 is deposited on the substrate 102, the first oblique plane 135, the bottom plane 136, and the second oblique plane 137, with a thickness 214 in the range of about 1 um to 10 um, and in some embodiments, the thickness 214 of the oxide layer 212 is greater than or equal to 7 um. However, other values and ranges are also within the scope of this disclosure.

At step 718, a reflection layer 216 is deposited on the oxide layer 212, as illustrated in FIG. 4F. As discussed above, the reflection layer 216 may be deposited via any suitable means including, for example and without limitation, chemical vapor deposition (CVD), physical vapor deposition (PVD), atomic layer deposition (ALD), sputtering, another deposition process, or any suitable combination thereof. In some embodiments, the reflection layer 216 may comprise, for example and without limitation, Al, AlCu, AlSiCu, AlSi, AlCr, or other suitable reflective metal, metal alloy, or the like. In accordance with other embodiments, the reflection layer 216 may comprise a plurality of layers of different reflective materials or coatings. That is, the reflection layer 216 may be formed by depositing one or more high reflection coatings on a base layer such as, for example and without limitation, SiO2/TiO2, AlAs/GaAs, AlN/GaN, and the like. In accordance with some embodiments, the number of layers of high reflection material is greater than or equal to three layers, and may be greater than four layers of high reflection material. According to one embodiment, the reflection layer 216 may be formed with a thickness 220 in the range of about 1 um to 7 um, and in some embodiments, within the range of about 3 um to 5 um. However, other values and ranges are also within the scope of this disclosure.

At step 720 a photoresist 218 is deposited and patterned on the reflection layer 216, as illustrated in FIG. 4G. At step 722, the reflection layer 216 is etched to remove those portions uncovered by the photoresist. FIG. 4H provides an illustrative example of the reflection device trench structure 116 and reflection device 114 at this stage of fabrication. In accordance with one embodiment, the reflection device 114, corresponds to, for example and without limitation, a metal film, quarter-wave stack (high reflection coating/Bragg mirror, or the like. That is, the reflection device 114 is positioned the thickness 214 of the oxide layer 212 from the first oblique plane 135 at reflection device angle 224. The reflection device angle 224, as shown in FIG. 4H, may range from about 0° to 55° and, in some embodiments, in the range of about 0° to 45°. However, other values and ranges are also within the scope of this disclosure. In accordance with some embodiments, the reflection device 114 includes a length 222 that corresponds to the length of the first oblique plane 135. Accordingly, the length 222 of the reflection device 114 may be in the range of about 1 um to 20 um, and in some embodiments, may be greater than or equal to 10 um. However, other values and ranges are also within the scope of this disclosure. At step 724, additional oxide material is deposited on the oxide layer 212 and the reflection device 114 filling the reflection device trench structure 116, as illustrated in FIG. 4I.

In accordance with some embodiments disclosed herein, there is provided a photonic device and fabrication method that provides process integration in CMOS process flows. Further, the disclosed methods and devices provide both die level and wafer level improvements and benefits in testing. Thus, the additional metal film or quarter-wave stack, i.e., the reflection device 114, on the first oblique plane 135 of the trench structure 116 functions as a mirror to reflect laser light for operating the device 100. In some embodiments, the structure described herein provides additional benefits in manufacturing steps, enables the use of an external light source (as opposed to a mounted laser), and is capable of being rapidly tested for compliance.

In accordance with a first embodiment, there is provided a photonic device structure that includes a substrate having a topside oxide layer formed thereon. The structure also includes a silicon layer that is formed on the topside oxide layer, and one or more waveguide components that are formed in the silicon layer. In addition, the structure includes a reflection device trench structure that is formed in the silicon layer, and which includes a first oblique plane, a bottom plane, and a second oblique plane. The photonic structure also includes a reflection device that is formed adjacent to the first oblique plane, and which has a reflection device angle relative to the bottom plane and configured to direct light into a waveguide component.

In accordance with a second embodiment, there is provided a photonic semiconductor device that includes a substrate and a first topside oxide layer that is formed on the substrate. The device also includes a silicon layer that is formed on the first topside oxide layer, and which includes a strip waveguide component, a rib to strip waveguide component, and one or more rib waveguide components. The device further includes a reflection device trench structure that is formed in the silicon layer and which has a first oblique plane, a bottom plane, and a second oblique plane. In addition, the device includes a reflection device that is formed adjacent to the first oblique plane. The reflection device includes a reflection device angle relative to the bottom plane and configured to direct light into the strip waveguide component, the rib to strip waveguide component or the rib waveguide component.

In accordance with a third embodiment, there is provided a method of fabricating a photonic semiconductor device. The method includes forming a silicon layer on a first topside oxide layer of a substrate, and forming one or more waveguide components in the silicon layer. The method further includes etching to remove a portion of the silicon layer and the first topside oxide layer adjacent to the at least one waveguide component to expose the substrate. A hard mask is then formed on the exposed substrate. A reflection device trench structure is then formed in the substrate through the hard mask. The reflection device trench structure comprising a first oblique plane, a bottom plane, and a second oblique plane. An oxide layer is then deposited in the reflection device trench structure, such that the oxide layer is formed on the first oblique plane, the bottom plane, and the second oblique plane. Thereafter, a reflection device is formed on the oxide layer of the first oblique plane.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A photonic device structure, comprising:
a substrate including a topside oxide layer formed thereon;
a silicon layer formed on the topside oxide layer;
at least one waveguide component formed in the silicon layer;
a reflection device trench structure formed in the silicon layer, having a first oblique plane, a bottom plane, and a second oblique plane; and
a reflection device formed adjacent to the first oblique plane, the reflection device having a reflection device angle relative to the bottom plane and configured to direct light into the at least one waveguide component.

2. The photonic device structure of claim 1, wherein the reflection device trench structure further comprises an oxide layer formed thereon, and wherein the reflection device is formed on the oxide layer.

3. The photonic device structure of claim 2, wherein the oxide layer has a thickness in the range of 1 um to 10 um.

4. The photonic device structure of claim 1, wherein the reflection device further comprises a plurality of high reflection coatings.

5. The photonic device structure of claim 1, wherein the reflection device comprises a reflection device length in the range of 1 um to 20 um.

6. The photonic device structure of claim 1, wherein the reflection device is positioned at an angle between 0 and 55 degrees.

7. The photonic device structure of claim 1, wherein the first oblique plane has an angle relative to the substrate between 0 and 55 degrees.

8. The photonic device structure of claim 1, wherein the first oblique plane has a length in the range of 1 um to 20 um.

9. The photonic device structure of claim 1, wherein the reflection device has a thickness in the range of 1 um to 7 um.

10. A photonic semiconductor device comprising:
a substrate;
a first topside oxide layer formed on the substrate;
a silicon layer formed on the first topside oxide layer, the silicon layer comprising:
a strip waveguide component,
a rib to strip waveguide component, and
at least one rib waveguide component;
a reflection device trench structure formed in the silicon layer, having a first oblique plane, a bottom plane, and a second oblique plane; and
a reflection device formed adjacent to the first oblique plane, the reflection device having a reflection device angle relative to the bottom plane and configured to direct light into at least one of strip waveguide component, the rib to strip waveguide component or the at least one rib waveguide component.

11. The photonic semiconductor device of claim 10, wherein the reflection device trench structure further comprises an oxide layer formed thereon, and wherein the reflection device is formed on the oxide layer.

12. The photonic semiconductor device of claim 11, wherein the reflection device further comprises a plurality of high reflection coatings.

13. The photonic device of claim 12, wherein the reflection device comprises at least one of a metal or a quarter-wave stack.

14. The photonic device of claim 13, wherein the quarter-wave stack comprises at least one high-reflection coating or Bragg mirror.

15. The photonic device of claim 11, wherein the first oblique plane has an angle relative to the substrate between 0 and 55 degrees.

16. The photonic device of claim 11, wherein the reflection device further comprises:
a reflection device length in the range of 1 um to 20 um;
a reflection device angle between 0 and 55 degrees; and
a reflection device thickness in the range of 1 um to 7 um.

17. The photonic device of claim 16, wherein the first oblique plane has an angle relative to the substrate between 0 and 55 degrees, and wherein the first oblique plane has a length in the range of 1 um to 20 um.

18. A method of fabricating a photonic semiconductor device, comprising:
forming a silicon layer on a first topside oxide layer of a substrate;
forming at least one waveguide component in the silicon layer;
etching to remove a portion of the silicon layer and the first topside oxide layer adjacent to the at least one waveguide component to expose the substrate;
forming a hard mask on the substrate;
forming a reflection device trench structure in the substrate through the hard mask, the reflection device trench structure comprising a first oblique plane, a bottom plane, and a second oblique plane;
depositing an oxide layer in the reflection device trench structure, the oxide layer formed on the first oblique plane, the bottom plane, and the second oblique plane; and
forming a reflection device on the oxide layer of the first oblique plane.

19. The method of claim 18, wherein forming the reflection device further comprises:
depositing a reflection layer on the oxide layer;
patterning a photoresist on the reflection layer to define the reflection device;
etching the reflection layer to form the reflection device.

20. The method of claim 19, wherein depositing the reflection layer further comprises depositing a plurality of high-reflection coatings.
